(19) United States
(12) Patent Application Publication
(10) Pub. No.: US 2019/0068084 A1
(43) Pub. Date: Feb. 28, 2019

(54) ENERGY HARVESTER AND METHOD FOR CONVERTING KINETIC ENERGY TO ELECTRICAL ENERGY

(71) Applicant: Airbus Operations Limited, Bristol (GB)

(72) Inventors: Christophe PAGET, Bristol (GB); Muhammad Abdul REHMAN, Bristol (GB)

(21) Appl. No.: 16/106,616

(22) Filed: Aug. 21, 2018

(30) Foreign Application Priority Data
Aug. 22, 2017 (GB) 1713451.1

(51) Int. Cl. H02N 2/18; H01L 41/113; B64D 45/00

(52) U.S. Cl. CPC H02N 2/183; H01L 41/1132; B64D 2045/0085; H02N 2/186; B64D 45/00; H02N 2/185

(57) ABSTRACT

An energy harvester (1) converts kinetic energy into electrical energy. The energy harvester includes: one or more walls (3, 4, 5, 6, 7) defining a chamber (2), the chamber (2) being provided with a plurality of impactors (10) free to move within the chamber so as to impact at least one of the walls when the chamber is subjected to movement, and a transducer (9, 11) configured to convert the impact of the impactors on one or more of the walls into electrical energy.

### BACKGROUND OF THE INVENTION

The present disclosure relates to an energy harvester for converting kinetic energy into electrical energy.

The present invention concerns the conversion of kinetic energy into electrical energy. More particularly, but not exclusively, this invention concerns an energy harvester for converting kinetic energy into electrical energy. The invention also concerns a method of generating electrical energy from kinetic energy, a method of providing electrical power to a load and an apparatus comprising an energy harvester and an electrical load.

Wireless sensor technology has been used across many different industries. Such sensors obviously require power, albeit typically low amounts of power. Such power may, for example, be provided by batteries, but these need replacing periodically which may be inconvenient, particularly if the batteries are located in a position which is difficult to access. Efforts have been made to design alternative power sources which do not need to be replaced or which can provide electrical power to rechargeable batteries. In this connection, M. Umeda et al. (“Analysis of the Transformation of Mechanical Impact Energy to Electric Energy Using Piezoelectric Vibrator”, Jpn. J. Appl. Phys., vol. 35, 1996, pages 3267-3273) describes how a dropped ball may cause vibrations when dropped onto a piezoelectric vibrator, those vibrations generating electrical power. C. Delebarre et al. (“Power Harvesting Capabilities of SHM Ultrasonic Transducers”, Smart Materials Research, Vol. 2012, Article ID 387638) describes how a vibrating piezoelectric cantilever may be used to generate electrical power. Such a cantilever has one or more natural modes of vibration and therefore the electrical signal generated will depend on the driving frequency. WO2016/113199 describes an energy harvester in which impact of a ball on a wall is used to drive the motion of a housing which is mounted using springs. The motion of the housing causes the generation of an electrical signal. This output of this energy harvester is strongly frequency-dependent because the spring-mounted housing has a natural vibration frequency.

The present invention seeks to mitigate one or more of the above-mentioned problems. Alternatively or additionally, the present invention seeks to provide an alternative and/or improved energy harvester.

### SUMMARY OF THE INVENTION

In accordance with a first aspect of the present invention, there is provided an energy harvester for converting kinetic energy into electrical energy, the energy harvester comprising:

one or more walls defining a chamber,
the chamber being provided with a plurality of impactors free to move within the chamber so as to impact at least one of the walls when the chamber is subjected to movement, and
a transducer configured to convert the impact of the impactors on one or more of the walls into electrical energy.

The plurality of impactors may be free to move within the chamber so as to impact more than one of the walls and optionally each of the walls when the chamber is subjected to movement.

The number of impactors provided in the chamber may depend on, inter alia, the size of the chamber and the size of the impactors. The chamber may be provided with at least 5, optionally at least 10, optionally at least 20, optionally at least 30, optionally at least 40, optionally at least 100, optionally at least 60, optionally at least 70 impactors, optionally at least 80, optionally at least 100, optionally at least 200, optionally at least 300, optionally at least 400, optionally at least 500, optionally at least 600, optionally at least 700 and optionally at least 800 impactors.

The chamber may be provided with no more than 10,000 impactors, optionally no more than 9,000 impactors, optionally no more than 8,000 impactors, optionally no more than 7,000 impactors, optionally no more than 6,000 impactors, optionally no more than 5,000 impactors, optionally no more than 4,000 impactors, optionally no more than 3,000 impactors, optionally no more than 2,000 impactors and optionally no more than 1,000 impactors, optionally no more than 800 impactors, optionally no more than 600 impactors, optionally no more than 500 impactors, optionally no more than 400 impactors, optionally no more than 300 impactors, optionally no more than 200 impactors, optionally no more than 180 impactors, optionally no more than 160 impactors, optionally no more than 140 impactors, optionally no more than 120 impactors, optionally no more than 100 impactors, optionally no more than 80 impactors, optionally no more than 60 impactors, optionally no more than 40 impactors and optionally no more than 20 impactors.

Optionally, the chamber may be provided with from 5 to 100 impactors, optionally from 20 to 100 impactors and optionally from 40 to 80 impactors. Such numbers of impactors are typically used if the impactors are relatively large.

Optionally, the chamber may be provided with from 100 to 5000 impactors, optionally from 500 to 3000 impactors and optionally from 800 to 2000 impactors. Such numbers of impactors are typically used in the impactors are relatively small.

The impactors may have a mean greatest dimension of no more than 3.0 cm, optionally no more than 2.0 cm, optionally no more than 1.0 cm, optionally no more than 0.8 cm, optionally no more than 0.6 cm, optionally no more than 0.5 cm, optionally no more than 0.4 cm, optionally no more than 0.3 cm, optionally no more than 0.2 cm, optionally no more than 0.1 cm, optionally no more than 0.05 cm, optionally no more than 0.03 cm and optionally no more than 0.025 cm.

The impactors may have a mean greatest dimension of at least 0.01 cm, optionally at least 0.015 cm, optionally at least 0.02 cm, optionally at least 0.03 cm, optionally at least 0.04 cm, optionally at least 0.05 cm, optionally at least 0.1 cm, optionally at least 0.2 cm, optionally at least 0.3 cm, optionally at least 0.4 cm and optionally at least 0.5 cm.

The impactors may have a mean greatest dimension of from 0.05 to 2.0 cm, optionally of from 0.1 to 1.0 cm, optionally of from 0.1 cm to 0.8 cm and optionally of from 0.2 cm to 0.6 cm. This size of impactor is typically used if a relatively small number of impactors is provided.

The impactors may have a mean greatest dimension of from 0.01 to 0.2 cm and optionally of from 0.02 to 0.15 cm, and optionally of from 0.05 cm to 0.15 cm. This size of impactor is typically used if a relatively small number of impactors is provided.

As mentioned above, if the impactors are relatively large, then fewer will be used in a chamber. In this connection, for relatively large impactors, the chamber may be provided with at least 5, optionally at least 10, optionally at least 20, optionally at least 30, optionally at least 40, optionally at least 50, optionally at least 60 and optionally at least 70 impactors. The chamber may be provided with no more than 200 impactors, optionally no more than 180 impactors, optionally no more than 160 impactors, optionally no more than 140 impactors, optionally no more than 120 impactors, optionally no more than 100 impactors, optionally no more than 80 impactors, optionally no more than 60 impactors, optionally no more than 40 impactors and optionally no more than 20 impactors. Optionally, the chamber may be provided with from 5 to 100 impactors, optionally from 20 to 100 impactors and optionally from 40 to 80 impactors. Such relatively large impactors the impactors may have a mean greatest dimension of no more than 3.0 cm, optionally no more than 2.0 cm, optionally no more than 1.0 cm, optionally no more than 0.8 cm, optionally no more than 0.6 cm, optionally no more than 0.5 cm, optionally no more than 0.4 cm and optionally no more than 0.3 mm. Such relatively large impactors may have a mean greatest dimension of at least 0.05 cm, optionally at least 0.1 cm, optionally at least 0.2 cm, optionally at least 0.3 cm, optionally at least 0.4 cm and optionally at least 0.5 cm. Such relatively large impactors may have a mean greatest dimension of from 0.05 to 2.0 cm, optionally of from 0.1 to 1.0 cm, optionally of from 0.1 cm to 0.8 cm and optionally of from 0.2 cm to 0.6 cm. For the avoidance of doubt, the use of the term “relatively large” is used to identify the size of the impactors used with the number of impactors stated in this paragraph.

Conversely, if impactors are relatively small, then more will be used. In this connection, for relatively small impactors which will be described below, the chamber may be provided with at least 100, optionally at least 200, optionally at least 300, optionally at least 400, optionally at least 500, optionally at least 600, optionally at least 700 and optionally at least 800 impactors. The chamber may be provided with no more than 10,000 impactors, optionally no more than 9,000 impactors, optionally no more than 8,000 impactors, optionally no more than 7,000 impactors, optionally no more than 6,000 impactors, optionally no more than 5,000 impactors, optionally no more than 4,000 impactors, optionally no more than 3,000 impactors, optionally no more than 2,000 impactors and optionally no more than 1,000 impactors. Optionally, the chamber may be provided with from 100 to 5000 impactors, optionally from 500 to 3000 impactors and optionally from 800 to 2000 impactors. The relatively small impactors which would typically be used in such high numbers would optionally have a mean greatest dimension of no more than 1.0 cm, optionally no more than 0.75 cm, optionally no more than 0.5 cm, optionally no more than 0.2 cm, optionally no more than 0.1 cm, optionally no more than 0.05 cm, optionally no more than 0.03 cm and optionally no more than 0.025 cm. These impactors may have a mean greatest dimension of at least 0.01 cm, optionally at least 0.015 cm, optionally at least 0.02 cm, optionally at least 0.03 cm, optionally at least 0.06 cm and optionally at least 0.1 cm. These impactors may have a mean greatest dimension of from 0.01 to 0.2 cm and optionally of from 0.02 to 0.15 cm, and optionally of from 0.05 cm to 0.15 cm.

The impactors provided in the chamber may be of uniform shape and size. Alternatively, the impactors provided in the chamber need not be of uniform shape and size. For example, the chamber may be provided with impactors of a certain shape (e.g. spherical) but of a non-uniform size (i.e. not all of the impactors are the same size).

At least one, optionally more than one, optionally a majority, and optionally all of the plurality of impactors may be spherical, spheroid (including oblate and prolate spheroid), ovoid, cylindrical, elongate or star-shaped.

The chamber may be any suitable shape. For example, the chamber may be cuboid in shape, for example, a cube or rectangular cuboid. The chamber may be cylindrical or spherical.

The chamber should be of sufficient size to permit the impactors to move about and, during such movement, come into contact with a wall. In certain circumstances, for example, if the energy harvester functions as a result of vibrations imparted to the chamber, then if the chamber is too large the vibrations may not be of sufficient force to cause the impactors to strike the walls forming the chamber.

The maximum dimension of the chamber may be no more than 100 mm, optionally no more than 75 mm, optionally no more than 50 mm and optionally no more than 25 mm.

The maximum dimension of the chamber may be at least 5 mm, optionally at least 10 mm, optionally at least 15 mm and optionally at least 20 mm.

The ratio of the maximum dimension of the chamber to the mean maximum dimension of the impactors may be at least 1.5:1, optionally at least 2:1, optionally at least 3:1, optionally at least 5:1 and optionally at least 10:1.

The ratio of the maximum dimension of the chamber to the mean maximum dimension of the impactors may be no more than 100:1, optionally no more than 50:1, optionally no more than 20:1, optionally no more than 10:1, optionally no more than 5:1, optionally no more than 3:1 and optionally no more than 2:1.

If the chamber is defined by more than one wall, not all of the walls need to be associated with the transducer to provide an electrical signal. For example, the energy harvester may be configured so that impacts on only one wall generate a significant electrical signal. This may occur, for example, if a transducer is coupled to a single wall. Alternatively, the energy harvester may be configured so that impacts on two walls will generate a significant electrical signal. This may be achieved, for example, by coupling a first transducer to a first wall and a second transducer to a second wall.

The energy harvester may comprise more than one transducer. For example, one transducer may be coupled to a first wall, and another transducer may be coupled to a second wall.

The transducer may comprise a piezoelectric transducer. At least a portion of one or more of the walls may be formed from piezoelectric material i.e. the walls provide part of the transducer, in which case there is no need for the transducer to be provided separately from and in addition to the walls. This may provide a more sensitive and/or powerful energy harvester.

Alternatively or additionally, at least one wall is formed from non-piezoelectric material, said wall being coupled to the transducer so that impacts of the impactors on said wall cause the transducer to generate an electrical signal.

The energy harvester may be a spring-free device. Devices provided with springs typically use springs to facilitate large amplitude motions which generate correspondingly large amounts of electrical energy. Such devices typically have a natural frequency of oscillation and their output may be strongly frequency-dependent.

The energy harvester may comprise a plurality of chambers, at least one of which is provided with a plurality of impactors free to move within the chamber so as to impact at least one of the walls when the chamber is subjected to movement. The other chambers are optionally provided with at least one impactor free to move within the chamber so as to impact at least one of the walls when the chamber is subjected to movement. Optionally, more than one of said plurality of chambers is provided with a plurality of impactors free to move within the chamber so as to impact at least one of the walls when the chamber is subjected to movement. Optionally, each of said plurality of chambers is provided with a plurality of impactors free to move within the chamber so as to impact at least one of the walls when the chamber is subjected to movement. Optionally, the same number of impactors may be provided in each chamber.

If the energy harvester comprises a plurality of chambers, then each chamber may be at least partially defined by a wall. Adjacent chambers may be separated by a wall, the wall partially defining each of the adjacent chambers.

One or more of the walls defining the chambers may comprise (and may optionally be formed from) piezoelectric material. This may provide a more sensitive and/or powerful energy harvester.

More than one and optionally a majority of, and optionally each of the plurality of chambers may be the same shape and/or size.

The energy harvester may comprise a plurality of substantially cuboid chambers. The chambers are optionally of the same shape and optionally of the same size. Each cuboid chamber is optionally provided with a plurality of impactors.

The energy harvester may be configured to provide an electrical power of at least 1 mW, optionally at least 2 mW, optionally at least 3 mW and optionally at least 4 mW. The energy harvester may, for example, be configured to provide a power of about 5 mW.

The energy harvester may be configured to provide electrical power in response to vibrations, such as the vibrations of at least part of an aircraft. In this case, in use, the vibration would cause vibrational movement of the chamber, causing relative movement of the impactors and the walls defining the chamber, resulting in impacts between the impactors and the walls of the chamber, thereby generating electrical energy. For example, the energy harvester may be configured to provide electrical power responsive to vibrations having a maximum frequency of 300 Hz and optionally of 250 Hz. The energy harvester may be configured to provide electrical power responsive to vibrations having a frequency range of from 0.01 Hz to 1 KHz, optionally of from 0.1 Hz to 500 Hz and optionally of from 1 Hz to 300 Hz.

The energy harvester may be configured to provide electrical power in response to fluid flow, such as the flow of fuel in part of an aircraft, such as a fuel flow line.

The chamber may be rotatably mountable. The energy harvester may comprise one or more mounts which permit rotation of the chamber, typically two mounts, optionally with the chamber located between two such mounts. The energy harvester may comprise one or more vanes configured to impart a rotational force to the chamber when exposed to a fluid flow. The vane(s) may optionally be attached to the chamber wall(s). One or more vanes may be curved. One or more impactor lifting surfaces may be provided within the chamber. Such lifting surfaces are configured to lift one or more impactors within the chamber when the chamber is rotated. One or more of the impactor lifting surfaces may extend inwardly into the chamber from a wall which at least partially defines the chamber. If the chamber is elongated (for example, if the chamber is substantially cylindrical), then one or more of the impactor lifting surfaces may extend in a direction along the length of the chamber.

According to a second aspect of the invention there is also provided an apparatus comprising an energy harvester in accordance with the first aspect of the present invention and an electrical load, the energy harvester being configured to supply electrical power to the electrical load, optionally via a charge storage device.

Such an apparatus facilitates the provision of electrical energy from an energy harvester in accordance with the first aspect of the present invention to an electrical load. Any electrical charge generated by the energy harvester may optionally be stored in a charge storage device before being supplied to the electrical load. For the avoidance of doubt, the charge storage device (if present) is part of the apparatus in accordance with the second aspect of the invention.

The load may optionally comprise a sensor. The sensor may comprise a sensor for an aircraft, such as a structural health monitoring sensor, a temperature sensor, a pressure sensor, a gas sensor (such as a nitrogen or oxygen sensor), a humidity sensor, a proximity sensor, an inertia sensor, a speed sensor or a torque sensor.

The load may comprise a transmitter, such as a wireless transmitter. The load may comprise a sensor associated with a transmitter, such as a wireless transmitter.

The load may comprise an indicator, such as a visual indicator, for example, a display and/or a source of light, such as a light emitting diode. The indicator may comprise an audible indicator, such as an audible alarm.

In accordance with a third aspect of the present invention, there is provided a method of generating electrical energy from kinetic energy, the method comprising;

Providing a chamber with a plurality of impactors therein;
Moving the chamber so as to cause one or more of the impactors to impact a surface defining the chamber, said impact causing the generation of electrical energy.

The method may comprise providing piezoelectric material arranged so that impact of one or more impactors on said surface defining the chamber causes the piezoelectric material to generate electrical energy.

Moving the chamber may comprise vibrating the chamber. This may be achieved by coupling the chamber to a source of vibration so that the vibrations of the source of vibrations are transmitted to the chamber.

Moving the chamber may comprise rotating the chamber. This may be achieved by subjecting the chamber to a fluid flow, and optionally mounting the chamber so that it rotates when subjected to said fluid flow.

The method of the third aspect of the present invention may take place in a vehicle, such as an aircraft.

The method of the third aspect of the present invention may be performed using an energy harvester, such as the energy harvester of the first aspect of the present invention. The method of the third aspect of the present invention may be performed using an energy harvester having one or more of the features of the energy harvester of the first aspect of the present invention.

In accordance with a fourth aspect of the present invention, there is provided a method of providing electrical power to a load, the method comprising;

Providing an electrical load; and
Providing electrical power to said load in accordance with the method of the third aspect of the present invention, optionally via a charge storage device.

The method of the fourth aspect of the present invention may take place, for example, in a vehicle, such as an aircraft.

The electrical load may have one or more of the features described above in relation to the apparatus of the second aspect of the present invention.

In accordance with a fifth aspect of the present invention, there is provided a monitoring system comprising an apparatus according to the second aspect of the present invention, in which the electrical load of the apparatus of the second aspect of the present invention comprises a sensor configured to transmit information wirelessly to a receiver. The receiver is typically located remote from the sensor. The monitoring system may be an aircraft monitoring system. In this case, the receiver may be located in an avionics bay of an aircraft, or elsewhere in the aircraft.

In accordance with a sixth aspect of the present invention, there is provided a device arranged to convert kinetic energy into electrical energy, wherein the device comprises a chamber containing a plurality of masses which are movable within the chamber, and a piezoelectric transducer associated with the chamber; and wherein the piezoelectric transducer is arranged to provide an electrical signal in response to one of the masses impacting a wall of the chamber.

The term ‘or’ shall be interpreted as ‘and/or’ unless the context requires otherwise.

It will of course be appreciated that features described in relation to one aspect of the present invention may be incorporated into other aspects of the present invention. For example, the method of the invention may incorporate any of the features described with reference to the apparatus of the invention and vice versa.

### DESCRIPTION OF THE DRAWINGS

Embodiments of the present invention will now be described by way of example only with reference to the accompanying schematic drawings of which:

FIG. 1 shows a schematic “see through” side-on view of an energy harvester according to a first embodiment of the invention;

FIG. 2 shows a schematic view of an apparatus according to an embodiment of the invention comprising the energy harvester of FIG. 1 and a sensor;

FIG. 3 shows a schematic flow chart of a method of generating electrical energy from kinetic energy and a method of providing electrical power to an electrical load according to an embodiment of the invention;

FIG. 4 shows a schematic view of an aircraft comprising a monitoring system according to an embodiment of the invention;

FIG. 5a shows a schematic “see through” side-on view of a [notional] energy harvester according to a further embodiment of the invention;

FIG. 5b shows a schematic “see through” end-on view of the energy harvester of FIG. 5a;

FIG. 6 shows a schematic “see through” side-on view of a [notional] energy harvester according to a further embodiment of the invention; and

FIG. 7 shows a schematic “see through” perspective view of a [notional] energy harvester according to yet a further embodiment of the invention.

### DETAILED DESCRIPTION

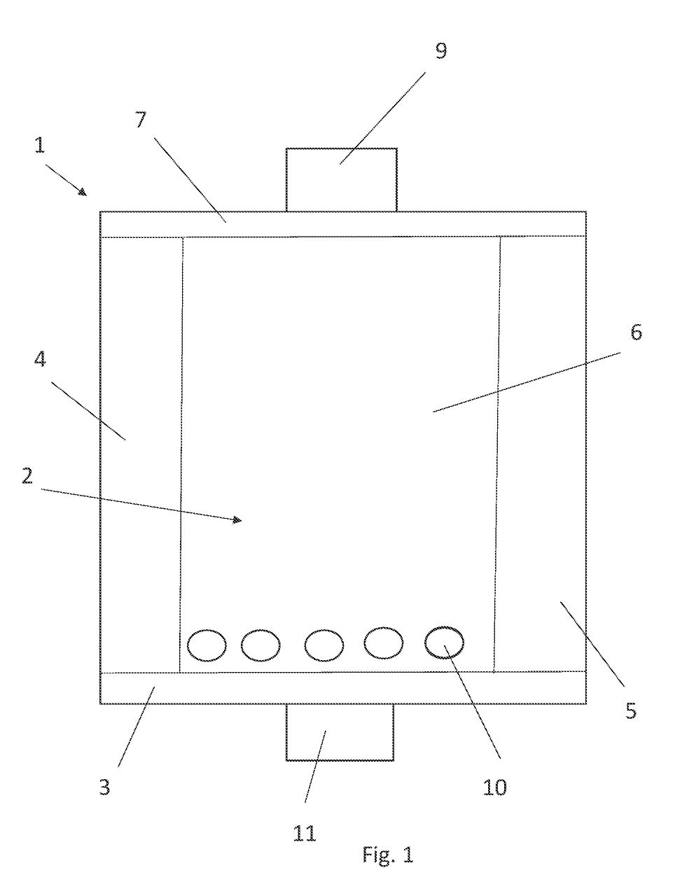

An embodiment of an energy harvester in accordance with the present invention will now be described with reference to FIG. 1. The energy harvester, denoted generally by reference numeral 1, comprises a chamber 2 defined by six walls, five of which 3, 4, 5, 6 and 7 are shown. The front wall has been omitted for clarity. Eighty impactors (only one of which is labelled 10) are located within chamber 2. A piezoelectric transducer 9 is bonded to wall 7, and a further piezoelectric transducer 11 is bonded to wall 3.

Walls 3, 4, 5 and 6 in the present case are 3 mm thick aluminium. The thickness of wall 7 is 2 mm. It is most likely desirable to use thinner walls (for example, 0.5 mm or 1 mm thick) in order to reduce weight and the amount of material used, and to possibly increase the electrical output of the energy harvester.

In this example, the impactors are stainless steel spheres (in this case, the balls from a ball bearing) having a nominal diameter of 2 mm.

The chamber 2 is a 1″ (25.4 mm) cube.

For testing, the energy harvester 1 was mounted on the upper jaw of a fatigue coupon tester which was used to vibrate energy harvester 1. The energy harvester 1 was mounted with piezoelectric transducer 9 attached to the upper jaw of the coupon tester. The coupon tester was cycled at a frequency of 3 Hz, and the electrical output of the energy harvester was monitored for 10 seconds. The vibration of the harvester 1 caused relative movement of the chamber and the impactors, causing the impactors to hit the walls defining the chamber 2. Given the up-and-down movement of the coupon tester, it is expected that the impactors would impact walls 3 and 7 more frequently than the other walls. In any case, the impact of the impactors with the walls of the energy harvester generated an electrical signal. The signal was recorded using an oscilloscope, and was rectified and processed in order to generate a power value. A total of 2.46×10⁻⁴ mW power was generated by the transducers 9 and 11.

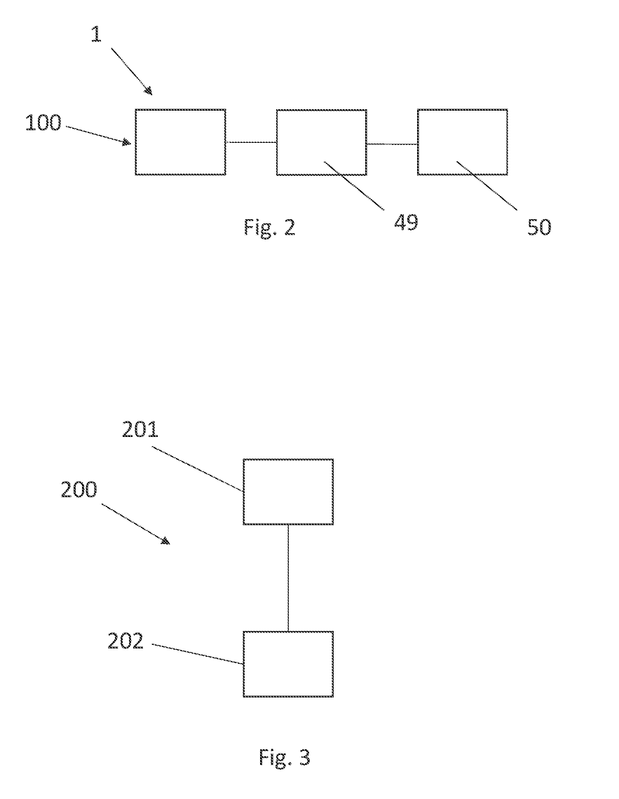

FIG. 2 shows an example of an embodiment of an apparatus in accordance with the present invention. The apparatus is denoted generally by reference numeral 100 and comprises energy harvester 1 electrically coupled and configured to provide electrical power to an electrical load which in this case is a sensor 50 via an electrical charge storage device 49, such as a rechargeable battery. Those skilled in the art will recognise that the electrical signal generated by the energy harvester 1 will be subject to vibration, such as aircraft vibration, and therefore the electrical output of the energy harvester will not be entirely predictable or uniform. Therefore, typically, suitable electronic components (such as diodes and capacitors) are provided in the electrical path between the energy harvester and the sensor 50 so that electrical energy is delivered to the sensor in the desired manner. Examples of circuitry which may be used in the electrical path between the energy harvester and the sensor 50 may be found in “Aircraft structures take advantage of energy harvesting implementations”, T. Armstrong, High Frequency Electronics, May 2010, pages 50-58. The sensor 50 in this case is a structural health monitoring sensor. A wireless transmitter (not shown in FIG. 2) is associated with each sensor 50 for transmitting information wirelessly from the sensor 50 to a remote receiver.

FIG. 3 shows an example of an embodiment of a method in accordance with the present invention. The method is denoted generally by reference numeral 200 and comprises providing 201 a chamber comprising a plurality of impactors, and an electrical load, and moving 202 the chamber so as to cause one or more of the impactors to impact a surface defining the chamber, said impact causing the generation of electrical energy, and providing electrical energy to the electrical load.

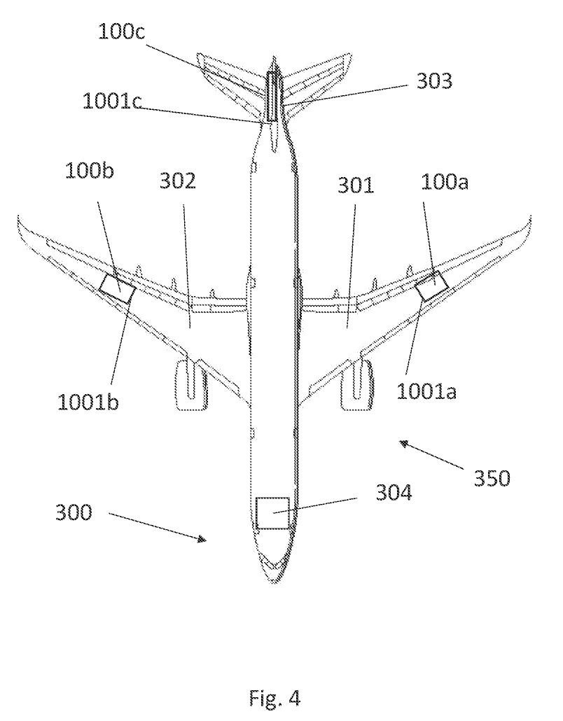

FIG. 4 shows a schematic plan view of an aircraft 300 provided with an embodiment of a monitoring system in accordance with the present invention, the system being generally denoted by reference numeral 350. The system 350 comprises a plurality of apparatus 100a, 100b, 100c, each of which is essentially the same as apparatus 100 described above in relation to FIGS. 1 and 2, and a receiver 304 located in the avionics bay (not labelled) of the aircraft 300. Apparatus 100a, 100b are each attached to a respective wing 301, 302, and apparatus 100c is attached to tail fin (vertical stabiliser) 303. Each apparatus 100a, b, c is provided with a respective structural health monitoring sensor. Each sensor is associated with a respective wireless transmitter (1001a, b, c) which transmits information from the respective structural health monitoring sensor to receiver 304.

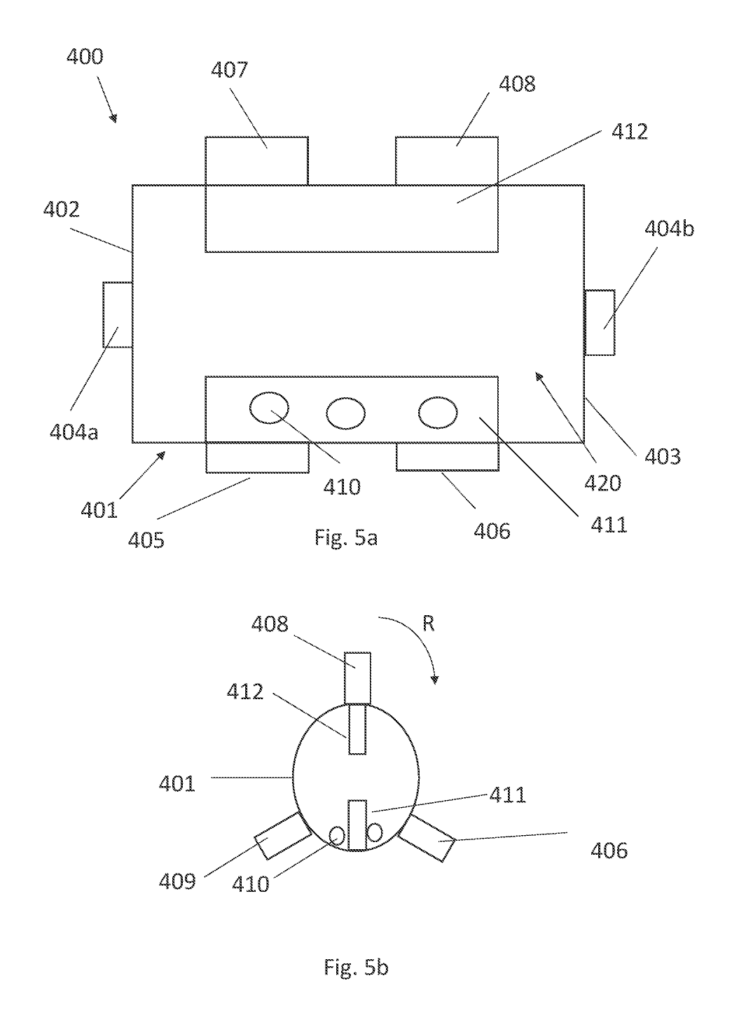

FIGS. 5a and 5b show a further embodiment of an energy harvester. The energy harvester is denoted generally by reference numeral 400, and differs from the energy harvester of FIG. 1 in that energy harvester 400 is moved by fluid flow (not vibration), as will now be explained. Energy harvester 400 is rotatably mountable via coaxial mounts 404a, 404b. These mounts permit rotation of chamber 420 which is defined by a cylindrical wall 401 and end plates 402, 403. Cylindrical wall 401 comprises piezoelectric material. The wall may comprise a piezoelectric ceramic material as is well-known to those skilled in the art of piezoelectric materials and as are widely available (see, for example, https://www.piceramic.com/en and https://www.americanpiezo.com). Alternatively, a thin film of piezoelectric material may be deposited onto a supporting substrate, as is well-known to those skilled in the art (see, for example, “Thin-film Piezoelectric MEMS”, Chang-Beom Eom at al., MRS Bulletin, Vol. 37, November 2012, pages 1007-1017). Chamber 420 is provided with a plurality of impactors, only one of which 410 is labelled. Each impactor is a stainless steel sphere. Also disposed within the chamber 420 are two impactor lifters 411, 412. Six vanes, only five of which are labelled (405, 406, 407, 408, 409), are attached to the surface of the cylinder 401. In use, the energy harvester 400 is located in a fluid flow path, for example, in a fuel tank or fuel pipeline of an aircraft, mounted with the rotational axis formed by mounts 404a, 404b not quite parallel to the direction of flow of the fluid. This permits the flow of the fluid to impact the vanes 405-409 so that the vanes cause the energy harvester 400 to rotate, for example, in direction R as indicated in FIG. 5b. Those skilled in the art will realise that curved vanes could be used, in which case, the rotational axis formed by mounts 404a, 404b may be placed substantially parallel to the direction of fluid flow. As is evident from FIG. 5b, as the energy harvester 400 rotates in direction R, impactor 410 is lifted by impactor lifter 411. At a certain elevation, impactor 410 will fall off impactor lifter 411 and fall onto cylindrical wall 401. The impact of falling impactor 410 with the piezoelectric cylindrical wall 401 causes an electrical signal to be generated.

Those skilled in the art will realise that the number, shape and size of the impact lifters can be varied.

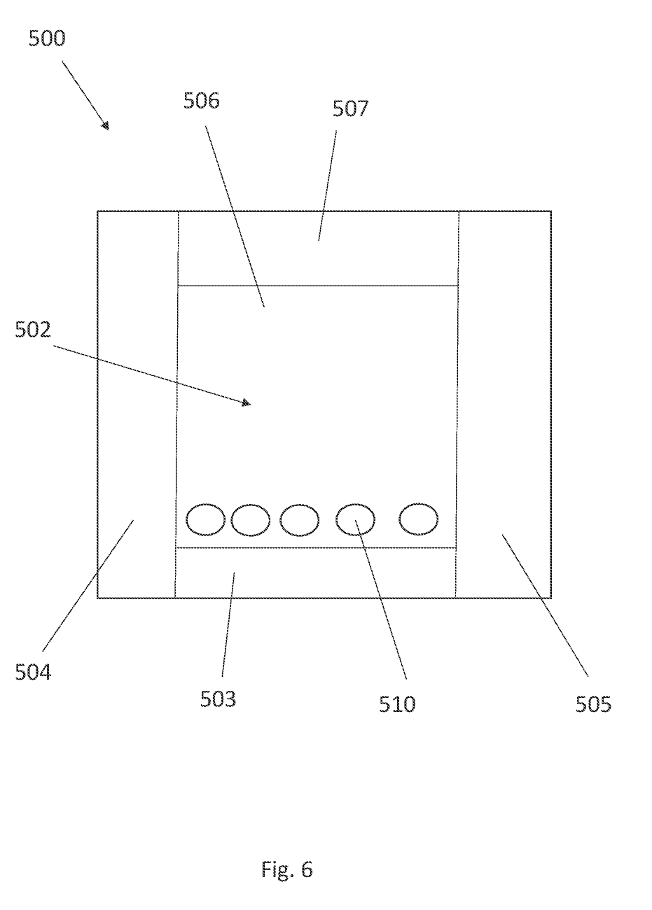

FIG. 6 shows a further embodiment of an energy harvester. The energy harvester is denoted generally by reference numeral 500, and is similar to that described above with reference to FIG. 1 because it functions based on vibration. Energy harvester 500 comprises a chamber 502 defined by six walls, five of which are labelled 503, 504, 505, 506, 507. The front wall has been omitted for clarity. Each wall comprises piezoelectric material. The walls may comprise a piezoelectric ceramic material as is well-known to those skilled in the art of piezoelectric materials and as are widely available (see, for example, https://www.piceramic.com/en and https://www.americanpiezo.com). Alternatively, a thin film of piezoelectric material may be deposited onto a supporting substrate, as is well-known to those skilled in the art (see, for example, “Thin-film Piezoelectric MEMS”, Chang-Beom Eom at al., MRS Bulletin, Vol. 37, November 2012, pages 1007-1017). This is different from the energy harvester of FIG. 1, which was provided with two piezoelectric transducers, each of which was coupled to a non-piezoelectric aluminium wall. The chamber 502 is provided with a plurality of impactors 510 in the form of aluminium balls, substantially as described above. During use, the energy harvester 500 is subject to vibrations. Those vibrations cause movement of the impactors relative to the chamber, and cause impacts between the walls and the impactors. Those impacts generate electrical energy which may be used to power a load, such as a sensor, as described above in relation to FIG. 2.

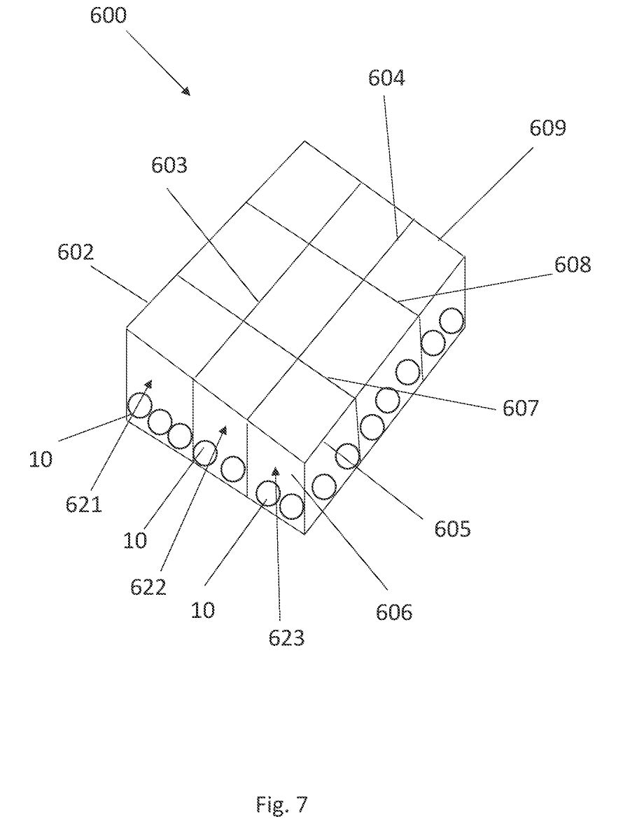

FIG. 7 shows a further embodiment of an energy harvester. The energy harvester is denoted generally by reference numeral 600, and is similar to those described above with reference to FIGS. 1 and 6 because it functions based on vibration. Energy harvester 600 comprises a plurality of chambers, three of which 621, 622, 623 are labelled. The chambers are defined by two series of walls, a first series of walls 602, 603, 604, 605 extending in one direction, and a second series of walls 606, 607, 608, 609 extending normal to the first series of walls. The walls are made from piezoelectric material. The walls may comprise a piezoelectric ceramic material as is well-known to those skilled in the art of piezoelectric materials and as are widely available (see, for example, https://www.piceramic.com/en and https://www.americanpiezo.com). Alternatively, a thin film of piezoelectric material may be deposited onto a supporting substrate, as is well-known to those skilled in the art (see, for example, “Thin-film Piezoelectric MEMS”, Chang-Beom Eom at al., MRS Bulletin, Vol. 37, November 2012, pages 1007-1017). Each chamber is provided with a plurality of impactors, several of which are labelled 10. Those impactors are substantially the same as those described above in relation to different embodiments. During use, the energy harvester 600 is subject to vibrations. Those vibrations cause movement of the impactors relative to the chamber, and cause impacts between the walls and the impactors. Those impacts generate electrical energy which may be used to power of load, such as a sensor, as described above in relation to FIG. 2.

Whilst the present invention has been described and illustrated with reference to particular embodiments, it will be appreciated by those of ordinary skill in the art that the invention lends itself to many different variations not specifically illustrated herein. By way of example only, certain possible variations will now be described.

The examples above show how the apparatus for converting kinetic energy into electrical energy may be used in aircraft. Those skilled in the art will realise that the apparatus may be used in other ways. For example, the apparatus which uses a flow of fluid to move the casing may be used in any situation in which there is a fluid flow. Similarly, the apparatus using vibration as a stimulus may be used with any potential source of vibration, such as other vehicles, backpacks and wallets. Such energy harvesters may be used to help power personal devices, such as mobile phones, laptop computers and tablet computers.

The examples above describe the use of spherical impactors. Those skilled in the art will realise that impactors of other shapes may be used, for example, cylinders, oblate spheroids, prolate spheroids, near-spheroids or ovoids. The impactors may be hollow or solid. For example, hollow cylindrical impactors have been found to be effective. Those skilled in the art will realise that the impactors used in any energy harvester need not be of the same size and/or shape.

The examples above describe the supply of electrical power to structural health monitoring sensors. Those skilled in the art will realise that electrical power may be supplied to other electrical loads, particularly those which may be powered by the relatively low amounts of power generated. For example, the energy harvesters which operate on fluid flow may be used to power fuel tank sensors, such as temperature, pressure, nitrogen or oxygen sensors. Energy harvesters which operate on fluid flow may be subject to air flow (for example, associated with movement of the aircraft), and may be used to power sensors which monitor ambient conditions, such as air pressure and air temperature.

Where in the foregoing description, integers or elements are mentioned which have known, obvious or foreseeable equivalents, then such equivalents are herein incorporated as if individually set forth. Reference should be made to the claims for determining the true scope of the present invention, which should be construed so as to encompass any such equivalents. It will also be appreciated by the reader that integers or features of the invention that are described as preferable, advantageous, convenient or the like are optional and do not limit the scope of the independent claims. Moreover, it is to be understood that such optional integers or features, whilst of possible benefit in some embodiments of the invention, may not be desirable, and may therefore be absent, in other embodiments.

1. An energy harvester for converting kinetic energy into electrical energy, the energy harvester comprising:
one or more walls defining a chamber,
the chamber being provided with a plurality of impactors free to move within the chamber so as to impact at least one of the walls when the chamber is subjected to movement, and
a transducer configured to convert the impact of the impactors on one or more of the walls into electrical energy.

2. (canceled)

3. The energy harvester according to claim 1, in which the plurality of impactors is free to move within the chamber so as to impact each of the walls when the chamber is subjected to movement.

4. The energy harvester according to claim 1, wherein the chamber is provided with at least 10 but no more than 200 impactors or is provided with at least 100 and no more than 4,000 impactors.

5. The energy harvester according to claim 4, in which the impactors have a mean greatest dimension of from 0.05 cm to 1.0 cm or a mean greatest dimension of from 0.01 cm to 0.3 cm.

6-7. (canceled)

8. The energy harvester according to claim 1, in which the impactors provided in the chamber are of uniform shape and size.

9-10. (canceled)

11. The energy harvester according to claim 1, in which the ratio of the maximum dimension of the chamber to the mean maximum dimension of the impactors is from 3 to 20.

12. The energy harvester according to claim 1, in which the chamber is defined by more than one wall, and not all of the walls are associated with the transducer to provide an electrical signal.

13-16. (canceled)

17. The energy harvester according to claim 1, in which the transducer comprises a piezoelectric transducer.

18-20. (canceled)

21. The energy harvester according to claim 1, in which the chamber is rotatably mountable.

22. (canceled)

23. The energy harvester according to claim 1, comprising one or more vanes configured to impart a rotational force to the chamber when exposed to a fluid flow.

24. The energy harvester according to claim 1, comprising one or more impactor lifting surfaces provided within the chamber, the one or more lifting surfaces being configured to lift one or more of the impactors within the chamber when the chamber is rotated.

25. The energy harvester according to claim 1, comprising a plurality of chambers, at least one of which is provided with the plurality of impactors free to move within the chamber so as to impact at least one of the walls when the chamber is subjected to movement.

26. (canceled)

27. The energy harvester according to claim 25, in which each of the plurality of chambers are the same shape and/or size.

28. (canceled)

29. The energy harvester according to claim 1, configured to provide electrical power responsive to vibrations having a frequency of from 0.5 to 2 kHz.

30. The energy harvester according to claim 1, configured to provide electrical power in response to fluid flow.

31. An apparatus comprising an energy harvester in accordance with claim 1, further comprising an electrical load, wherein the energy harvester is configured to supply electrical power to the electrical load.

32. The apparatus according to claim 31 in which the electrical load comprises one or more of a sensor, a transmitter and an indicator.

33-42. (canceled)

43. The apparatus according to claim 31, wherein the electrical load includes a sensor and the apparatus includes a receiver located remote from the sensor, and the receiver is configured to receive for information transmitted from the sensor.

44. The apparatus in accordance with claim 43, wherein the apparatus is an aircraft monitoring system.

45. A device arranged to convert kinetic energy into electrical energy, wherein the device comprises:
a chamber containing a plurality of masses which are movable within the chamber, and a piezoelectric transducer associated with the chamber;
wherein the piezoelectric transducer is arranged to generate an electrical signal in response to the masses impacting a wall of the chamber.

46. The device of claim 45 wherein the chamber is rotatably mounted in a liquid fuel flow path of a fuel system in an aircraft, and the chamber is configured to be rotated by liquid fluid flowing through the flow path.

47. The device of claim 45 wherein an interior surface of the chamber is formed of a piezoelectric material, and the plurality of masses are arranged in the chamber to impact against the interior surface.
